(19) United States
(12) Patent Application Publication
(10) Pub. No.: US 2007/0267732 A1
(43) Pub. Date: Nov. 22, 2007

(54) Circuit card module and method for fabricating the same

(75) Inventors: Toniady Tan, Taichung Hsien (TW); Cheng-Chung Yu, Taichung (TW); Hung-Chi Wei, Taichung (TW); Chih-Hou Chang, Taichung (TW); Huan-Shiang Li, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/801,303

(22) Filed: May 8, 2007

(30) Foreign Application Priority Data
May 9, 2006 (TW) 095116338

(51) Int. Cl. H01L 23/02; H01L 21/00

(52) U.S. Cl. 257/679; 438/121; 257/E23.064

(57) ABSTRACT

A circuit card module and a method for fabricating the same are disclosed. The present invention includes the steps of providing a carrier having at least a first carrying region and a second carrying region that are co-planar; respectively mounting a substrate electrically connected to a first chip on the first carrying region, and a second chip electrically connected the substrate on the second carrying region, wherein the substrate is provided with at least an area of electrical connecting portion for being connected with external devices so as to reduce areas required for mounting a larger substrate or another substrate, thereby allowing a circuit card module to be fabricated with a minimized substrate.

### FIELD OF THE INVENTION

The present invention relates to circuit modules, and more particularly to a card type circuit module and a fabricating method thereof.

### BACKGROUND OF THE INVENTION

In the Digital Age, a card type circuit module such as a multi-media card (MMC) or a secure digital card (SD), which is a type of flash memory circuit module with high storage capacity, is developed. This type of circuit card module can be coupled to any data platform such as a personal computer (PC), a personal Digital Assistant (PDA), a digital camera and a multi-media browser, for storing and retrieving a variety of digital multi-media data.

The fabrication method of a prior-art circuit card module comprises the steps of: firstly, performing a chip mounting process to mount a chip on a substrate; secondly, electrically connecting the chip to electrical connection pads of the substrate by means of soldering via bonding wires; then performing an encapsulating process to form an encapsulant on the substrate for encapsulating the chip and the bonding wires disposed on the substrate; lastly, inserting the substrate and the encapsulant into a casing so as to form a card module. Similar techniques may be found in U.S. Pat. Nos. 5,677,524 and 6,040,622 and T.W. Patent No. 570,294.

Furthermore, referring to U.S. Pat. Nos. 5,677,524 and 6,040,622, both patents suggest having a plurality of chips directly stacked on the substrate. However, the thinnest substrate known to date is 210 μm thick and a typical chip is 75 μm thick. Therefore, as shown in FIG. 9, after deducting the thickness of the substrate 10 and casing 30 covering the encapsulant 20, only two chips 40 can be staked within the typical circuit card module. Accordingly, due to the thickness of the substrate, the amount of the chips that can be staked in the circuit card module is strongly limited in the prior arts. In addition, as employing a substrate with large surface areas for staking the chips is essential to the prior-art invention, it results in a high cost of production.

T.W. Patent No. 570,294, on the other hand, discloses another type of circuit card modules, using a substrate with a smaller size of 10 mm*18 mm as a chip carrier. Thus the substrate can be reduced to almost the same size as the area covered by the chip in order to lower the cost of production.

Nowadays, in order to satisfy consumer's ever-increasing demand for higher quality multimedia, a lot of new digital devices are developed to have better performances and more functions. For example, a new digital camera may boost its performance by improving its resolution of 1 million pixels to 5 million pixels or more. In response to that, the memory capacity of the circuit card module must be increased correspondingly. For instance, an earlier product can only hold a capacity of 32 MB, 64 Mb, or 128 Mb, but now it can hold a capacity of 1 GMb up to 4 GMb. In order to upgrade the memory capacity, the size of the chip has to be increased correspondingly. However, according to the teachings of T.W. Patent No. 570,294, the size of the substrate has to be correspondingly increased as well in order to accommodate the enlarged chip that has larger memory capacity. In other words, when the memory capacity and size of the chip increases, the substrate of T.W. Patent No. 570,294 must be increased in size, leading to an increase of substrate material cost. Accordingly, problems in having the limitation of chip stacking due to the thickness of the substrate and the high production cost are remained unsolved by the teachings of T.W. Patent No. 570,294.

Moreover, as the size and height of the circuit card module must be compatible with the specifications announced by Multi-Media Card Association (MMCA) and Secure Digital Association (SDA), it becomes a big challenge to upgrade the memory capacity within the limited space of the circuit card module.

Therefore, a need still remains for developing a circuit card module and the fabricating method thereof, which is capable of reducing the size of substrate, stacking multiple chips without being limited by the thickness of the substrate, preventing an increase in the size of the substrate due to variation of different chip size, as well as reducing the cost of production.

### SUMMARY OF THE INVENTION

In light of the shortcoming of the above prior arts, a primary objective of the present invention is to provide a circuit card module and a fabricating method thereof, which can minimize the size/thickness of a substrate.

Another objective of the invention is to provide a circuit card module and a fabricating method thereof, which can stack a plurality of chips without being limited by the thickness of a substrate.

Still another objective of the invention is to provide a circuit card module and a fabricating method thereof, which is capable of reducing the size of a substrate and making it compatible with different sizes of chips.

In order to achieve the foregoing and other objectives, the present invention discloses a circuit card module and a fabricating method therefore. The circuit card module comprises: a substrate providing a surface having a surface sufficiently large to form an electrical connecting portion thereon for electrically connecting to external devices; at least a first chip mounted on and electrically connected to the substrate; and at least a second chip electrically connected to the substrate, wherein at least a surface of the second chip is co-planar with the substrate.

In the foregoing circuit card module, the first chip is electrically connected to the substrate via bonding wires. The first chip may be a controller die and the second chip may be a memory die. In one preferred embodiment, a plurality of second chips are stacked over each other in a step-like manner and electrically connected to the substrate. In another preferred embodiment, the second chips are electrically connected to each other via bonding wires, wherein at least one of the second chips is electrically connected to the substrate via bonding wires.

The circuit card module may further comprise an encapsulant and a casing. The encapsulant is employed for encapsulating the first chip, the second chips, and the substrate, whereas the casing is employed for covering the encapsulant but allowing the electrical connecting portion to be exposed therefrom.

The fabricating method of the circuit card module disclosed by the present invention, comprises: providing a carrier defined with at least a first and a second carrying regions; respectively mounting a substrate having a first chip electrically connected thereto on the first carrying region, and at least a second chip electrically connected to the substrate on the second carrying region, wherein the substrate has at least a surface sufficiently large enough to form an electrical connecting portion thereon for electrically connecting to external devices.

In the foregoing fabricating method, the carrier may be a board selected from a group consisting a glass board, a plastic board, and a metallic board, wherein a surface of the carrier may be formed with an adhesive. In one preferred embodiment, the carrier may be a glass board and the adhesive layer may be an UV layer, wherein adhesiveness of the adhesive layer can be removed by means of UV light in order to remove the carrier. In another preferred embodiment, the carrier may be a plastic board and the adhesive layer may be an acrylic adhesive layer, wherein the adhesive layer can be removed by means of mechanical backgrinding in order to remove the carrier. Yet, in another preferred embodiment, the carrier may be a metallic layer and the adhesive may be an acrylic adhesive layer, wherein adhesiveness of the adhesive layer can be removed by means of chemical agents in order to remove the carrier.

Furthermore, in another preferred embodiment, a plurality of second chips are employed in a semiconductor package, wherein the second chips are electrically connected to each other via bonding wires. There are different ways of stacking the second chips on the carrier. For example, the second chips may be sequentially stacked on top of each other on the second carrying region, or be staked in a step-like manner in advance and then mounted on the second carrying region. Moreover, the substrate may be mounted on the first carrying region and electrically connected to the first chip, before stacking the second chips on the second carrying region. Yet, as another alternative, the substrate may be mounted on the first carrying region and the second chips may be stacked and mounted on the second carrying region, before respectively electrically connecting the first chips and the second chips to the substrate.

Preferably, the foregoing fabricating method further comprises the steps of: forming an encapsulant for encapsulating the substrate, the first chip and the second chips; removing the carrier. Moreover, after removing the carrier, a singulation process is performed. In addition, the foregoing fabricating method may further comprise the steps of: providing a casing for covering the encapsulant but allowing the electrical connecting portion to be exposed therefrom, wherein the casing may be pre-fabricated, or formed by injection modeling during fabrication processes. The present invention allows a plurality of semiconductor packages to be fabricated in batch, so as to reduce production cost.

Comparing to prior arts, as the substrate of the present invention only requires a minimum surface to form an electrical connecting portion for electrically connecting to external devices, only a small amount of the substrate materials will be consumed for fabricating a circuit card module. In addition, as aforementioned, because the present invention is capable of stacking multiple chips without being limited by the thickness of the substrate, the present invention can produce a circuit card module comprising more chips than the prior arts do. For instance, the present invention can deliver a circuit card module containing more than two staked chips. And withal, because the substrate of the present invention only need to comprise an electrical connecting portion thereof, the present invention can minimize the substrate size regardless of the size of the chips and increase memory capacity without changing the appearance of the circuit card module. Last but not the least, the carrier described herein may be re-used again and again after being removed from the substrate so as to reduce the cost of production. Accordingly, the present invention is a very valuable industrial application, which outperforms the prior arts by the foregoing unique advantages.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

The present invention can be more fully understood by reading the following detailed description of the preferred embodiments, with reference made to the accompanying drawings, wherein:

FIGS. 1 to 3 in conjunction with FIGS. 4A, 4B, and 4B′ disclose a schematic flowchart of the fabricating method of the circuit card module in accordance with a first preferred embodiment of the present invention;

FIGS. 5A to 5C in conjunction with FIG. 5A′ are schematic views of the fabricating method of the circuit card module in accordance with a second preferred embodiment of the present invention;

FIGS. 6A and 6B are schematic views of the circuit card module in accordance with a second preferred embodiment of the present invention, in which FIG. 6A is a cross-sectional view of the circuit card module while FIG. 6B is a top view of the FIG. 6A;

FIGS. 7 and 8 are schematic views of the circuit card module in accordance with a third preferred embodiment of the present invention; and

FIG. 9 (Prior Art) is a schematic view showing a prior-art circuit card module.

### DETAILED DESCRIPTION OF THE PREFERRED EMBODIMENTS

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing. Similarly, although the views in the drawings for ease of description generally show similar orientations, this depiction in the drawings. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

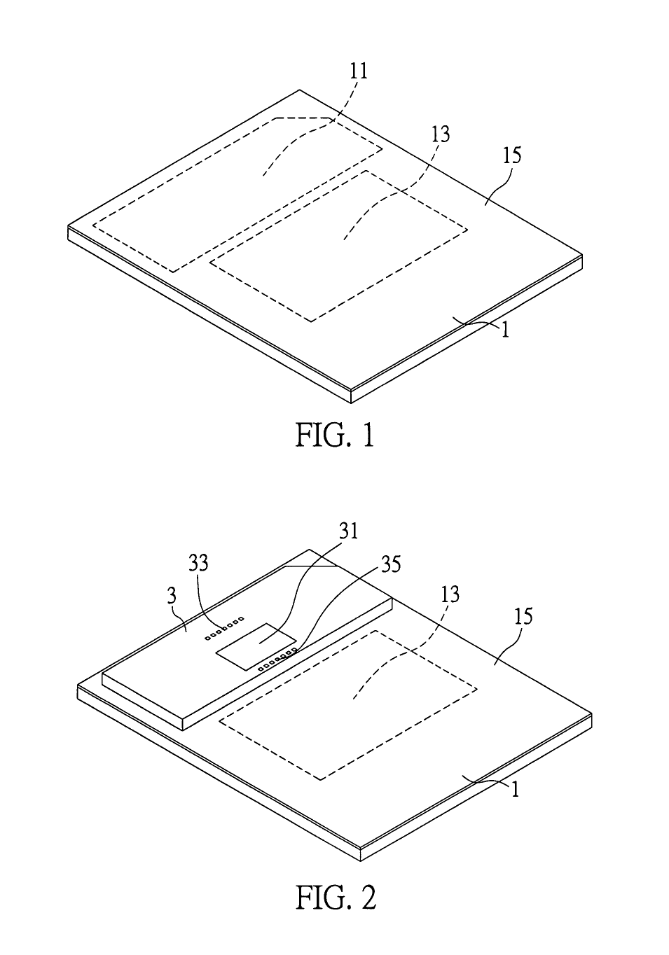

The first embodiment of the circuit card module of the present invention and the method of fabricating the same is illustrated in FIGS. 1 to 4B and exemplified using a multi-media card (MMC). However, the present invention can also be applied to form other types of circuit cards, which have different functions and sizes, such as SD cards.

In this preferred embodiment, the fabricating method of the circuit card module comprises: providing a carrier having at least a first carrying region and a second carrying region, wherein the first carrying region is co-planar with the second carrying regions; and, respectively, mounting a substrate that is electrically connected to a first chip on the first carrying region, and a second chip that is electrically connected to the substrate on the second carrying region. Additionally, any substrate that is sufficiently large enough for the substrate to be electrically connected to an external device may be employed.

Referring to FIG. 1, a carrier 1 is provided, which is predefined with a plurality of carrying regions. In this embodiment, the carrier 1 has a first carrying region 11 that is co-planar with a second carrying region 13. The carrier 1 may be made of a glass board. The carrier 1 may be further formed with an adhesive layer 15 such as an UV layer.

It should be noted that the carrier 1 of this preferred embodiment comprises the first carrying region 11 and the second carrying region 13, however, it should not be limited thereto. For instance, any carrier that is predefined with a first carrying region and a second carrying region may be employed. Moreover, the carrier 1 described herein may be a gold board, a plastic board, or any other types of boards made of other appropriate materials.

Next, a substrate 3 and a second chip 6 are respectively mounted on the first carrying region 11 and the second carrying region 13, wherein a first chip 5 is mounted on and electrically connected to the substrate 3 in subsequent processes.

Referring to FIG. 2, the substrate 3 is mounted on the first carrying region 11. In this preferred embodiment, the substrate 3 has a chip mounting region 31 on one surface thereof, a first electrical connecting portion 33, a second electrical connecting portion 35, and a third electrical connecting portion 37, wherein the first electrical connecting portion 33 and second electrical connecting portion 35 are formed around peripheries of the chip mounting region 31, and the third electrical connecting portion 37 is formed on one of the other surfaces of the substrate 3 (as shown in FIG. 4B). Furthermore, the first and second electrical connecting portions 33 and 35 are bond pads formed on the substrate 3. The third electrical connecting portion 37 is used for connecting with external devices (not shown). It should be noted that the fabrication process of this preferred embodiment is employed to fabricate a circuit card module as shown in the drawings, but is not limited thereto. In addition, any size of the substrate may be employed as long as it is sufficiently large enough to form the third electrical connecting portion 37 thereon for electrically connecting to external devices, thus it should not be limited to what have been described and illustrated herein.

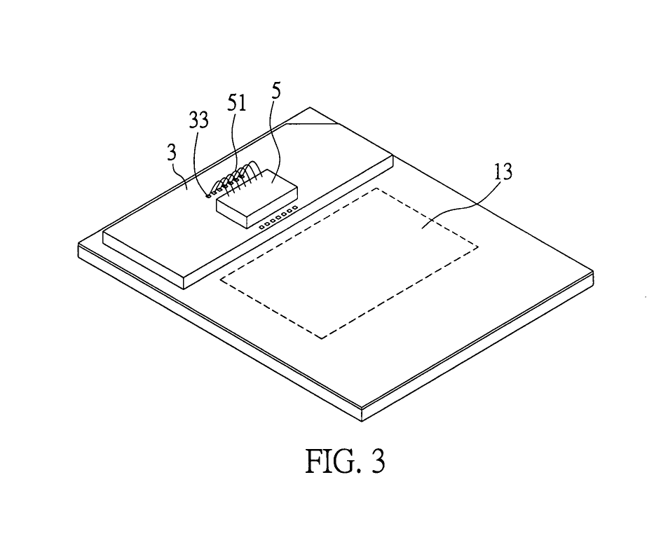

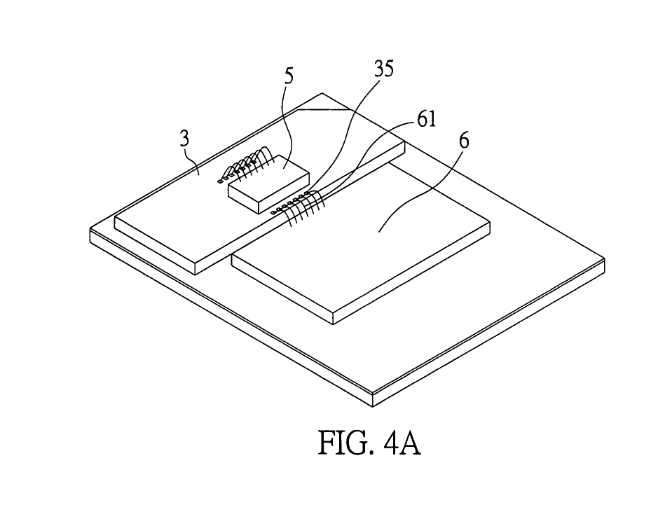

Subsequently, as shown in FIG. 3, a first chip mounting process is performed to dispose the first chip 5 on the chip mounting region 31, wherein the first chip 5 is electrically connected to the substrate 3. A first wire bonding process is performed to form bonding wires 51, such that the first chip 5 is electrically connected to the first electrical connecting portion 33 via the bonding wires 51, so as to allow the first chip 5 to be electrically connected to the substrate 3.

Then, referring to FIG. 4A, a second chip mounting process is performed to dispose the second chip 6 on the second carrying region 13, wherein the second chip 6 is disposed on a surface of the substrate 3. In this preferred embodiment, a second wire bonding process is performed to form bonding wires 61 for electrically connecting the second electrical connecting portion 35 to the second chip 6. Moreover, because of those innovative configurations described herein, the size of the substrate 3 employed for the circuit card module can be dramatically reduced, as long as the substrate 3 is sufficiently large enough to form the third electrical connecting portion 37 on a surface thereof that is free of the first chip 5.

Accordingly, a circuit card module at least comprises: a substrate 3 having a third electrical connecting portion 37 for electrically connecting to external devices, a first chip 5 disposed on the substrate 3, a second chip 6 electrically connected to the substrate 3, wherein the second chip 6 has a surface that is co-planar with the substrate 3. In this preferred embodiment, the first chip is a controller die and the second chip 6 is a memory die.

Yet, in order to increase memory capacity, the first carrying region ad second carrying region may respectively accommodate a substrate equipped with a first chip, and a plurality of second chips stacked on top of each other, wherein the first chip is electrically connected to the substrate.

Moreover, the a substrate and a plurality of second chips stacked on top of the other may be disposed on the first carrying region and the second carrying region respectively, and the first chip may be electrically connected to the substrate.

According to the foregoing, a third chip mounting process may be performed to increase memory capacity. As depicted in FIG. 4B, another second chip 6′ is stacked over the second chip 6, wherein the second chips 6 and 6′ are electrically connected to the substrate 3. In this preferred embodiment, a third wire bonding process is performed to form bonding wires 61 and 63. Furthermore, the bonding wires 61 are used for electrically connecting the second electrical connecting portion 35 of the substrate 3 to the second chip 6, and the bonding wires 63 are used for electrically connecting the second chip 6 to second chip 6′. This thereby allows the chip 5 to be electrically connected to the second chips 6 and 6′ via the substrate 3, and the bonding wires 61 and 63. It should be noted that, the fabricating procedure steps of this preferred embodiment are performed in the following sequences. First, the substrate 3 is disposed on the first carrying region 11. Subsequently, the substrate 3 is electrically connected to the first chip 5. Then a plurality of second chips 6 and 6′ are stacked on the second carrying region 13, and, lastly, each of the second chips 6 and 6′ is electrically connected to the substrate 3. However, the present invention should not be limited to the foregoing sequence. For example, the fabricating procedure steps may also be performed in the following sequences. A plurality of second chips 6 and 6′ are stacked the second chip carrying region 13 before disposing the substrate 3 on the first carrying region 11. And then the second chips 6 and 6′ are electrically connected to the substrate 3. Lastly, the first chip 5 is disposed on the substrate 3.

### Second Embodiment

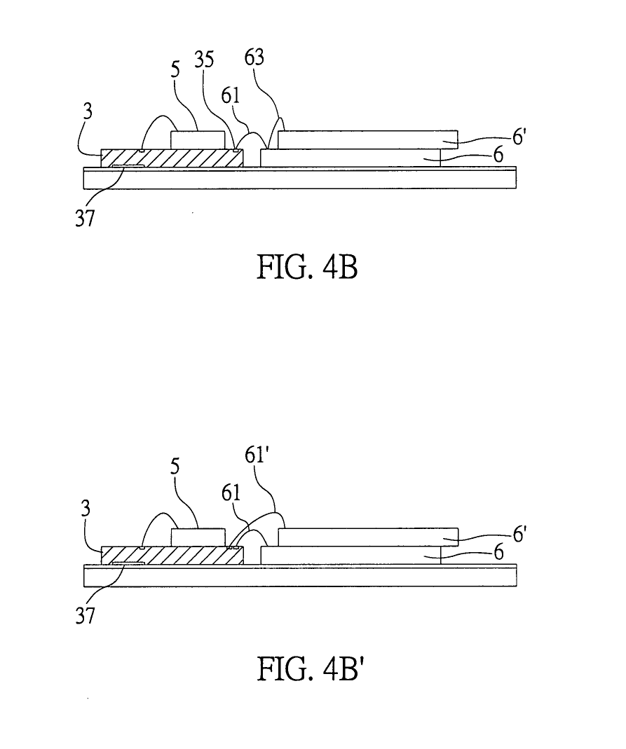

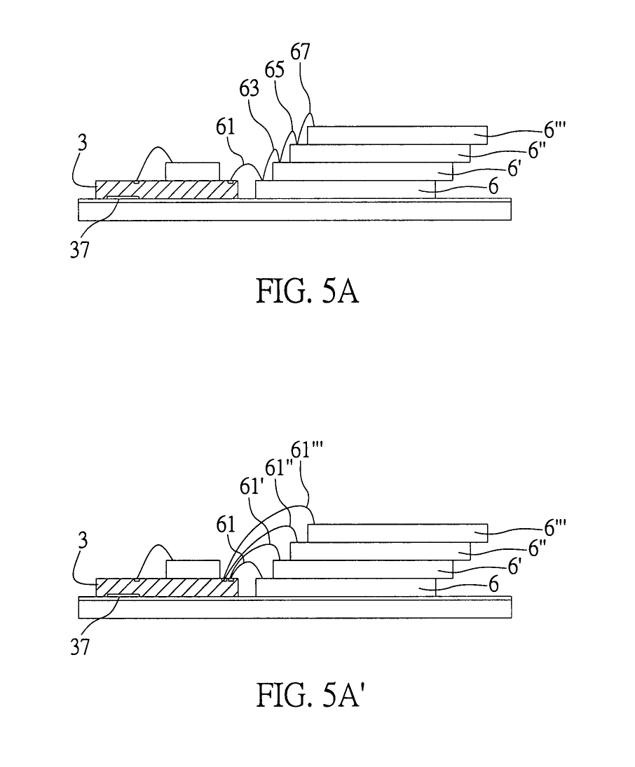

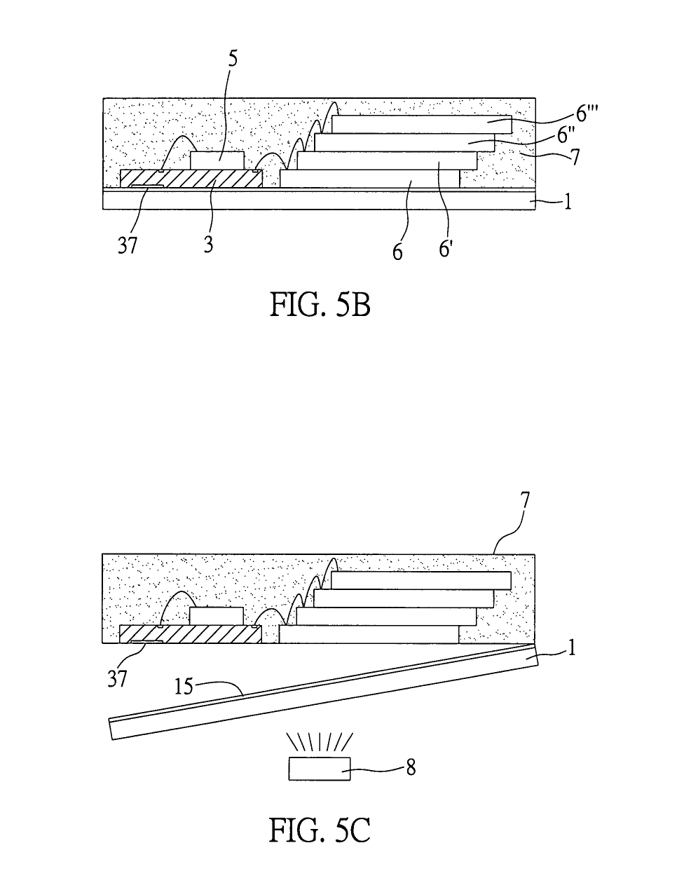

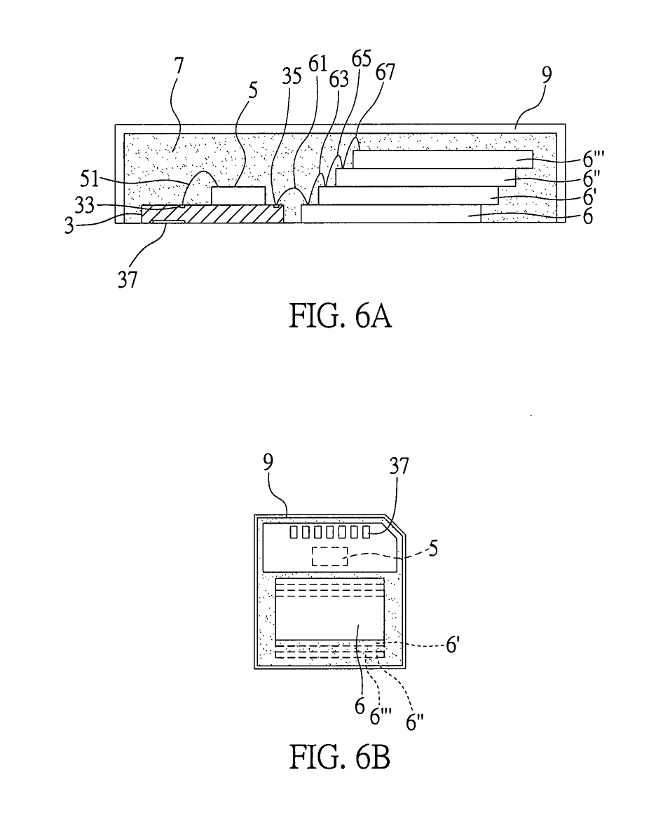

The schematic views of a second embodiment of the circuit card module of the present invention and the fabrication method thereof are shown in FIGS. 5A to 6B. Elements of the second embodiment that are deemed identical or similar to that of the first embodiment are represented by identical or similar reference numerals labeled in the first embodiment, and the detailed descriptions related to such elements are omitted, so as to make the specification simple and clear, but with sufficient information, for one with ordinary skill in the art to understand.

One of the major differences between the second embodiment and the first embodiment are that, in the first embodiment, only one or two chips are stacked on the carrier, and the size/thickness of the substrate are minimized; whereas, in the second embodiment, more than two second chips are stacked on the carrier without limiting the size/thickness of the substrate. In other words, the size/thickness of the substrate is highly adjustable, so as to allow the substrate to be compatible with the chips and the bonding wires formed thereon.

As shown in FIG. 5A, after stacking a plurality of second chips 6″ and 6″′ over the second chips 6 and 6′ of the first embodiment, a wire bonding process is performed to form a plurality of bonding wires 61, 63, 65 and 67. Referring to FIG. 5A, the second chip 6″′ is electrically connected to the second chip 6″ via the bonding wires 67, the second chip 6″ is electrically connected to the second chip 6′ via the bonding wires 65, the second chip 6′ is electrically connected to the second chip 6 via the bonding wires 63, and the second chip 6 is electrically connected to the substrate 3 via the bonding wires 61, such that the second chips 6, 6′, 6″ and 6″′ are electrically connected to each other and to the substrate 3 through the bonding wires 61, 63, 65 and 67. Alternatively, as depicted in FIG. 5A′, the second chips 6, 6′, 6″ and 6″′ may be directly electrically connected to the substrates through the bonding wires 61, 61′, 61″ and 61″′ respectively. In other words, the second chip 6″′ is directly electrically connected to the substrate 3 via the bonding wires 61″′, the second chip 6″ is electrically connected to the substrate 3 via the bonding wires 61″, the second chip 6′ is electrically connected to the substrate 3 via the bonding wires 61′, and to the substrate 3 via the bonding wires 61.

Next, as shown in FIG. 5B, an encapsulant 7 is formed to encapsulate the substrate 3, the first chip 5, and the second chips 6, 6′, and 6″′. The third electrical connecting portion 37 of the substrate 3 is connected to the carrier 1 by means of an adhesive without being covered by the encapsulant 7. In this embodiment, the encapsulant is formed by a molding process.

Subsequently, as shown in FIG. 5C, the carrier 1 is removed. In one embodiment, a light source 8 capable of emitting UV light may be employed to radiate the UV light to the bottom of the carrier 1, in order to make the adhesive layer 15 to loose its adhesiveness, so as to remove the carrier 1. It should be noted that, in this embodiment the carrier 1 is a glass board with an adhesive layer, however, in another embodiment the carrier 1 may be a plastic board made of plastic material and/or epoxy resin, and the adhesive layer 15 may be an acrylic adhesive layer, such that the carrier 1 can be removed by means of mechanical backgrinding. Alternatively, the carrier 1 may be a metallic board and the adhesive layer 15 may be an acrylic adhesive layer, thereby allowing the carrier 1 to be removed by means of chemical agents. In other words, one of ordinary skill in the art may adjust, modify or re-arrange the foregoing fabricating processes to prepare/make the carrier board 1 of different materials and to remove the carrier board 1 according to different demands.

Lastly, referring to FIG. 6A and FIG. 6B, FIG. 6B is the top view of FIG. 6A, wherein the encapsulant 7 is covered by a casing 9. Because the encapsulant 7 is sheltered in the casing 9, the surfaces of the stacked second chips 6, 6′, 6″ and 6″′ that are exposed to the encapsulant 7 can be protected from external damages.

Furthermore, as shown in FIGS. 6A and 6B, the circuit card module comprises a substrate 3 with a third electrical connecting portion 37 exposed from an encapsulant 7 for electrically connecting to an external device, a first chip 5 mounted on the substrate 3, and a plurality of second chips 6, 6′, 6″ and 6″′ electrically connected to the substrate 3, wherein at least a surface of at least one of the second chips 6, 6′, 6″ and 6″′ is co-planar with the substrate 3, the encapsulant 7 encapsulating the substrate 3, first chip 5, second chip 6, 6′, 6″ and 6″′, and a casing 9 covering the encapsulant 7.

In addition, any substrate of any size may be employed as long as it is has an area sufficiently large enough to form the third electrical connecting portion 37 thereon for electrically connecting to external devices. In this embodiment, the first chip 5 is disposed on the chip mounting region 31 and electrically connected to the first electrical connecting portion 33 via the bonding wires 51, wherein the first chip 5 is a controller die. Moreover, the stacked second chips 6, 6′, 6″ and 6″′ are electrically connected with each other via the bonding wires 63, 65 and 67, wherein second chips 6, 6′ 6″ and 6″′ are memory dies and the bonding wires 51, 61, 63, 65 and 67 are gold wires. The casing 9 may be pre-made, or directly formed by means of injection modeling during the fabricating process.

### Third Embodiment

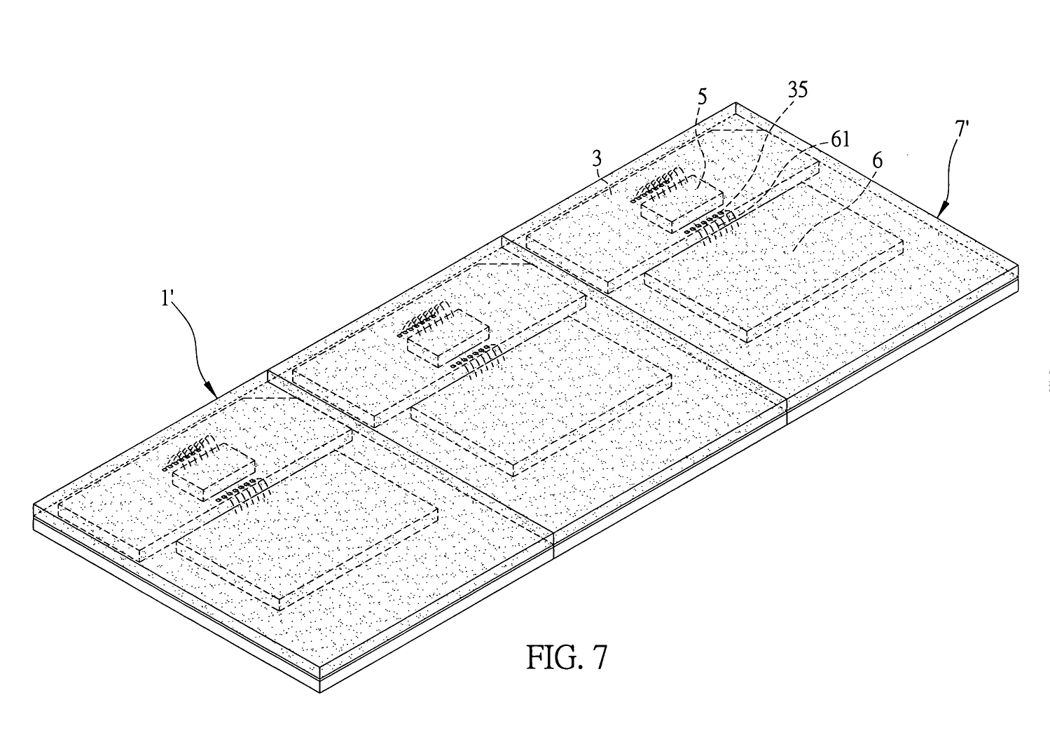

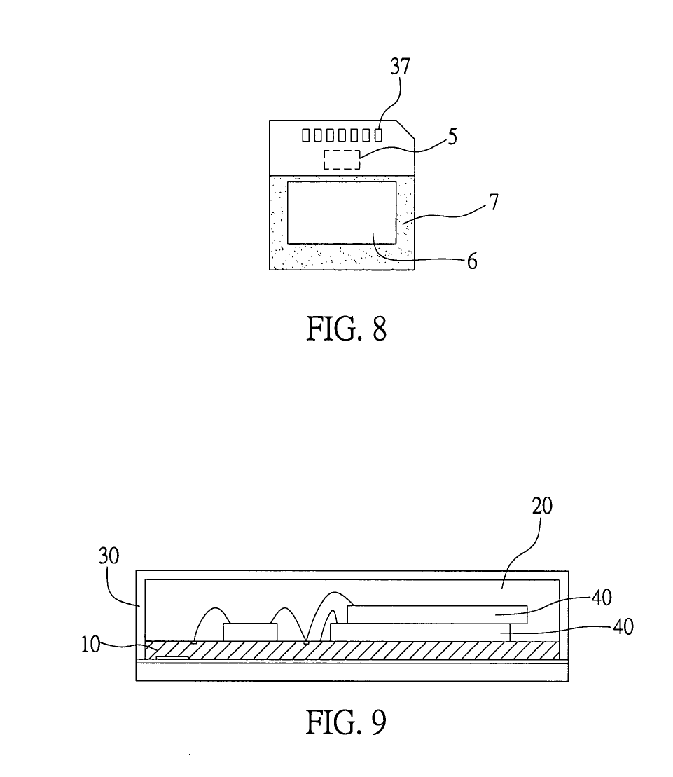

The schematic views of a third embodiment of the circuit card module of the present invention and the fabrication method thereof are shown in FIGS. 7 and 8. Elements of the third embodiment that are deemed identical or similar to that of the previous embodiments are represented by identical or similar reference numerals labeled in the foregoing embodiments, and the detailed descriptions related to such elements are omitted, so as to make the specification simple and clear, but with sufficient information, for one having ordinary skill in the art to understand.

Comparing the third embodiment to the first embodiment, one of the major differences therebetween is that an arrayed carrier is used to exemplify the third embodiment. In addition, the present embodiment can be applied to, but not limited to the fabrication of SD cards.

As shown in FIG. 7, the arrayed carrier 1′ is a strip-shaped arrayed carrier, which comprises a plurality of carriers arranged in a row, wherein a plurality of substrates 3 and second chips 6 are disposed on the arrayed carrier 1′. Furthermore, a first chip 5 and a second chip 6 having a surface co-planar with each of the substrates 3 are mounted on and electrically connected to each of the substrates. Next, an arrayed encapsulant 7′ having a plurality of encapsulants arranged in a row is formed for encapsulating the substrates 3, the first chips 5 and the second chips 6, thereby forming a plurality of semiconductor packages next to each other on the arrayed carrier 1′. Then the arrayed carrier 1′ is removed. Subsequently, a singulation process is preformed to separate the semiconductor packages from each other, so as to form a single circuit card, as shown in FIG. 8. Lastly, a casing 9 is provided to cover the encapsulant 7, thereby forming an individual circuit card module, as shown in FIG. 6B.

Accordingly, it should be understood by a person having ordinary skill in the art that the design, arrangement and configuration of the present invention is highly flexible. For example, the present invention may employ a miniaturized substrate or other substrates suitable for electrically connecting to chips. Moreover, the carrier for carrying the substrate, first chip, and second chip can be configured as a single unit or arranged in a row to form a multi-carrier array. In addition, in one embodiment, as the arrayed carriers may be fabricated in batch, the fabricating cost can thus be dramatically reduced.

Moreover, although four second chips 6, 6′, 6″ and 6″′ are used to exemplify the foregoing embodiments, circuit cards other than multi-media circuit cards may be employed in another embodiments. Furthermore, methods of stacking the chips and the number of the stacked chips can be adjusted or modified according to predetermined standards or industrial requirements. Therefore, alternatives of the foregoing embodiments should not be limited to what has been disclosed herein.

Besides, as the substrate 3 of the present invention does not have the second chips 6, 6′, 6″ and 6″′ attached thereto, the thickness of the substrate 3 will not affect the spaces available for stacking the second chips 6, 6′, 6″ and 6″′. In other words, a single layer circuit board or a multi-layered circuit board may be employed as the substrate.

Concluded from the above, the circuit card module of the present invention and the fabricating method thereof are capable of reducing 50% of materials used for the substrate by minimizing the size of the substrate, as compared to the prior art. In other words, the present invention can reduce the amount of fabrication materials used for the substrate to a minimum degree, thereby reducing the cost of production dramatically. Moreover, comparing to the prior art as shown in FIG. 9, the circuit card module of the present invention can reduce signal transmission paths between the second chips and the substrate, and that of between the second chips and the first chip, thereby improving electrical quality.

Last but not the least, in a circuit card module of any standard, the present invention provides much more spaces for stacking chips than the prior arts do. For example, the present invention is capable of stacking at least two more 75 μm chips in thickness as compared to the prior arts. Accordingly, the semiconductor package of the present invention is capable of accommodating more chips as well as reducing the size/thickness of and the material amount consumed by the substrate, without being limited by the sizes and the amount of chips.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A circuit card module, comprising:
a substrate having a surface sufficient to form an electrical connecting portion thereon for electrically connecting to external devices;
at least a first chip mounted on and electrically connected to the substrate; and
at least a second chip electrically connected to the substrate,
wherein at least a surface of the second chip is co-planar with the substrate.

2. The circuit card module of claim 1, wherein the first chip is electrically connected to the substrate via bonding wires.

3. The circuit card module of claim 1, wherein the first chip is a controller die.

4. The circuit card module of claim 1, wherein a plurality of second chips are stacked over each other and electrically connected to the substrate.

5. The circuit card module of claim 4, wherein the second chips are stacked in a step-like manner.

6. The circuit card module of claim 4, wherein the second chips are electrically connected to each other.

7. The circuit card module of claim 6, wherein the second chips are electrically connected to each other via bonding wires.

8. The circuit card module of claim 1, wherein at least one of the second chips is electrically connected to the substrate via bonding wires.

9. The circuit card module of claim 1, wherein the second chip is a memory die.

10. The circuit card module of claim 1, further comprising an encapsulant for encapsulating the first chip, the second chip and the substrate.

11. The circuit card module of claim 10, further comprising a casing covering the encapsulant but having the electrical connecting portion being exposed therefrom.

12. A method for fabricating a circuit card module, comprising:
providing a carrier defined with at least a first and a second carrying regions; and
respectively mounting a substrate having a first chip electrically connected thereto on the first carrying region, and at least a second chip electrically connected to the substrate on the second carrying region, wherein the substrate has at least an area sufficient to form an electrical connecting portion thereon for electrically connecting to external devices.

13. The fabricating method of claim 12, wherein the carrier is a board selected from a group consisting of a glass board, a plastic board and a metallic board.

14. The fabricating method of claim 12, wherein an adhesive layer is formed on a surface of the carrier.

15. The fabricating method of claim 14, wherein the carrier is a glass board and the adhesive layer is an UV layer.

16. The fabricating method of claim 15, wherein the carrier can be removed by making the adhesive layer to lose its adhesiveness via means of irradiation of a light source.

17. The fabricating method of claim 14, wherein the carrier is a plastic board and the adhesive layer is an acrylic adhesive layer.

18. The fabricating method of claim 18, wherein the carrier can be removed by means of mechanical backgrinding.

19. The fabricating method of claim 14, wherein the carrier is a metallic board and the adhesive layer is an acrylic adhesive layer.

20. The fabricating method of claim 19, wherein the carrier can be removed by making the adhesive layer to lose its adhesiveness via means of chemical agent.

21. The fabricating method of claim 12, wherein a plurality of second chips are disposed and electrically connected to each other via bonding wires.

22. The fabricating method of claim 21, wherein the second chips are sequentially stacked in a step-like manner on the second carrying region.

23. The fabricating method of claim 21, wherein before mounting the second chips on the second carrying region, the second chips are stacked in a step-like manner in advance.

24. The fabricating method of claim 21, wherein the substrate is mounted on the first carrying region and electrically connected to the first chip beforehand, and then the second chips are mounted on the second carrying region.

25. The fabricating method of claim 21, wherein the substrate and the stacked second chips are respectively mounted on the first carrying region and the second carrying region before electrically connecting the first chip and the second chips to the substrate.

26. The fabricating method of claim 12, wherein the substrate is mounted on the first carrying region and electrically connected to the first chip beforehand, and then the second chip is mounted on the second carrying region.

27. The fabricating method of claim 12, wherein the substrate and the second chip is respectively mounted on the first carrying region and the second carrying region in advance, and then the first and the second chips are electrically connected to the substrate.

28. The fabricating method of claim 12, further comprising:
forming an encapsulant for encapsulating the substrate, the first chip and the second chip; and
removing the carrier.

29. The fabricating method of claim 28, wherein the carrier is a strip-shaped carrier.

30. The fabricating method of claim 28, further comprising a singulation process.

31. The fabricating method of claim 28, further covering the encapsulant by a casing that allows the electrical connecting portion to be exposed therefrom.

32. The fabricating method of claim 31, wherein the casing is a pre-fabricated.

33. The fabricating method of claim 31, wherein the casing is formed by means of injection modeling.
